(19) United States
(12) Patent Application Publication
(10) Pub. No.: US 2020/0379062 A1
(43) Pub. Date: Dec. 3, 2020

(54) METHOD AND SYSTEM OF MAGNETIC POSITIONING

(71) Applicant: A-Fen Chang, Taipei City (TW)

(72) Inventor: Cheng-Tsai Ho, Taipei City (TW)

(21) Appl. No.: 16/886,987

(22) Filed: May 29, 2020

(30) Foreign Application Priority Data
May 31, 2019 (TW) 108118960

(51) Int. Cl. G01R 33/02; G01R 33/56

(52) U.S. Cl. CPC G01R 33/02; G01R 33/5608

(57) ABSTRACT

A method of magnetic positioning operates by detecting a plurality of real-time magnetic information of a moving path along a moving direction, decomposing each of the real-time magnetic information into a plurality of real-time magnetic values and selecting at least one of the real-time magnetic value corresponding to an axis of real-time magnetic field, selecting each of the reference magnetic information corresponding to each of the real-time magnetic information and selecting at least one of the axis of reference magnetic field and at least one of the reference magnetic value according to at least one of the axis of real-time magnetic field, and matching at least one of the real-time magnetic value corresponding to at least one of the axis of real-time magnetic field and at least one of the reference magnetic value corresponding to at least one of the axis of reference magnetic field to position the target.

### TECHNICAL FIELD

The present invention discloses a method and system of magnetic positioning, particularly, a method and system of magnetic positioning based on detecting real-time magnetic field information of resultant vectors as a basis for interpretation.

### BACKGROUND

With the development of technology, the functions of mobile devices such as smart phones and tablets are greatly improved, and through the mobile location services in mobile devices, users can get location information and even can use it for navigation. The existing mobile positioning services mainly use global positioning system (GPS), wireless communication positioning and other technologies to obtain the current location information of mobile devices.

The conventional global positioning system relies on the cooperation between satellites, control stations, and receivers for smooth operation. The global positioning system uses a three-dimensional positioning method, which usually requires the operation of at least four satellites. The receiver on the ground receives electromagnetic wave signals from satellites, and the coordinate position of the receiver is calculated according to the principle of triangulation. However, in the actual environment, there are many interferences. Generally, the distance between the satellite and the receiver is calculated by the time that the electromagnetic wave is transmitted from the satellite to the receiver, and then multiplied by the speed of the electromagnetic wave in the vacuum. The distance between the two is calculated, but when the electromagnetic wave is transmitted to the ionosphere and troposphere in the atmosphere, the speed and distance of the electromagnetic wave transmission will be affected, which will cause errors. Additionally, after the electromagnetic wave signal passes through the interference of the atmosphere and before it reaches the receiver, it will also be affected by the refraction or reflection of various terrains and features, such as in high-rise cities, elevated roads, bridge pier. In areas, such as, shelters, tunnels, indoors, or undulating terrain, the interference of buildings on the ground will also cause non-linear propagation of the signal. Certain errors will be introduced in the calculation, making the positioning errors larger and affecting the accuracy of positioning.

In addition to the GPS system, the commonly used positioning systems are wireless communication positioning (such as Bluetooth, WiFi, etc.). For conventional wireless communication in indoor positioning method, the wireless access points (WiFi Access Point) and wireless network interface controllers (WNIC) are commonly used for measuring the strength of the wireless signals and then locate the signals by matching the signal strength. In detail, in the wireless communication positioning method, firstly, the moving target detects the signals of reference nodes nearby and collects the location-independent variables such as the receiving time difference, the receiving angle and so on. Based on the above results, the distance between the moving target and each reference node can be calculated. Then, the triangular positioning method is exerted to position the moving target. Most wireless communications indicate the signal intensities via the received signal strength indicator (RSSI) and calculate the distance between the moving target and each reference node. However, the environmental conditions greatly interfere the results, then the accuracy become poor as the RSSI is used in long-distance position method or in outdoor position method. At present, the RSSI method is mostly applied to indoor positioning at short distances, or outdoor positioning with low accuracy.

To sum up, in the conventional technologies, whether a GPS system or a wireless communication positioning system, the positioning results are still not accurate enough for many applications. According to the measurement in different environments, the error of the conventional positioning methods often ranges from several meters to hundreds of meters, especially in areas with obstacles or undulating terrain, which make poor accuracy and limits the applications.

Accordingly, a method and system of magnetic positioning is disclosed in the present invention. The method and system can achieve high accuracy even in areas with obstacles or undulating terrain. Comparing to the conventional GPS and wireless communication technologies, the positioning results of the present invention would not be interfered from the atmospheric and other wireless communication signals.

### SUMMARY

A purpose of the present invention is to provide a method and system of magnetic positioning to detect at least a magnetic value of a single axis as the main positioning information. Comparing to the conventional magnetic detection technology, it is no longer to detect composite geomagnetic vectors. Especially, in the environment where there is a plurality of non-geomagnetic magnetic field, such as areas with a plurality of artificial buildings (bridges, buildings, etc.), and equipment with electromagnetic fields (poles, etc.). Different from the conventional positioning using geomagnetism vector, in the present invention, at least a magnetic value of a single axis is measured as the reference of the non-geomagnetic magnetic field feature, and/or is matched with the pre-configured magnetic information to position the moving target.

A purpose of the present invention is to provide a method and system of magnetic positioning to detect at least one of magnetic field intensity (H) and/or magnetic flux density (B) to accurately position the moving target. Hence, the problem of decreasing the accuracy of position caused via environmental variations, obstacle interferences, difficulty in identifying changes in height and so on can be solved. Therefore, the present invention can especially be suitable for the positioning the moving target on the roads. In the application of the natural environment, in addition to positioning on land, it can also be positioned in the sea, lake, and air at the same time.

A purpose of the present invention is to provide a method and system of magnetic positioning. As the detected magnetic information changes continuously with different locations, when the amount of detected magnetic information is sufficient, not only the area where the moving target can be positioned, but the precise position of the moving target can be accurately positioned as well. Hence, the present invention can provide higher resolution than the conventional methods. In practical applications, the moving target can be the transportations on the road, in/under the sea and in the air, such as the vehicles, ships, submarines, and airplanes. Or, the moving target can be any other devices or equipment such as the skateboards, paragliders, jet skis, etc. For the method disclosed in the present invention, the accuracy of the positioning can be increased via detecting and/or prediction of the transportations having certain path patterns due to moving along the existing moving path.

A purpose of the present invention is to provide a method and system of magnetic positioning to provide calculation logic for angle correction, filtering, and vectors. In practical applications, problems such as angular differences between the magnetic field detector and the actual magnetic field, background noise, etc. can be solved.

A purpose of the present invention is to provide a method and system of magnetic positioning. Based on different magnetic field in different axial would be contribute from different source, a specific magnetic value of an axis is selected for matching in order to improve the accuracy of magnetic position. Taking Cartesian coordinates as an example, the three axial magnetic field (physically, also named as the triaxial component of magnetic field) are independent of each other, which can be used to determine the direction, location, and vector of a non-geomagnetic magnetic field. Magnetic field in one or multiple axes can be used for matching to achieve magnetic position. Since the magnetic information detected is sufficient to represent the magnetic characteristics of each location, the information detected in the present invention can be used for positioning. In some specific cases, multiple specific magnetic values of axis can be further vectorized before matched. In some specific cases, the matching results in different axis can be weighted. The above-mentioned various information processing methods can be selectively matched to obtain the most appropriate results.

A method and system of magnetic positioning is disclosed in the present invention. The method and system of magnetic positioning of the present invention can position a moving target via referring to a plurality of reference magnetic information comprising a plurality of reference magnetic values corresponding to a plurality of axes of reference magnetic field. The method comprises a plurality of steps as following. Firstly, detecting a plurality of real-time magnetic information of a moving path along a moving direction of the moving target; secondly, decomposing each of the real-time magnetic information according to a plurality of axes of real-time magnetic field into a plurality of real-time magnetic values and selecting at least one of the real-time magnetic value corresponding to at least one of the axis of real-time magnetic field; then, selecting each of the reference magnetic information corresponding to each of the real-time magnetic information and selecting at least one of the axis of reference magnetic field and at least one of the reference magnetic value according to at least one of the axis of real-time magnetic field; finally, matching at least one of the real-time magnetic value corresponding to at least one of the axis of real-time magnetic field and at least one of the reference magnetic value corresponding to at least one of the axis of reference magnetic field to position the target.

Further, detecting a plurality of real-time magnetic information of a moving path is implemented via detecting a magnetic information of all magnetic objects in an environment.

Further, the axes of reference magnetic field and/or the axes of real-time magnetic field are built-in axes and/or self-defined axes.

Further, selecting at least one of the axis of real-time magnetic field is implemented according to a calculation of at least one of a magnitude of value, a relative variation (such as a magnitude of value and a variation of value) and a signal-to-noise ratio of each of the real-time magnetic value corresponding to the axis of real-time magnetic field.

Accordingly, the calculation of at least one of the magnitude of value, the relative variation (such as a magnitude of value and the variation of value) and the signal-to-noise ratio of each of the real-time magnetic value corresponding to the axis of real-time magnetic field is one-time or continuous.

Accordingly, as the signal-to-noise ratio calculation of each of the real-time magnetic value corresponding to the axis of real-time magnetic field is one-time, and selecting the axis of real-time magnetic field with a maximum signal-to-noise ratio.

Accordingly, as the signal-to-noise ratio calculation of each of the real-time magnetic value corresponding to the axis of real-time magnetic field is continuous, and non-adjustably or re-adjustably selecting one or more of the axis of real-time magnetic field according to the signal-to-noise ratio calculation in an order from high to low.

Further, before matching at least one of the real-time magnetic value corresponding to at least one of the axis of real-time magnetic field and at least one of the reference magnetic value corresponding to at least one of the axis of reference magnetic field, further calibrating at least one of the axis of real-time magnetic field and at least one of the axis of reference magnetic field via linear transformation method.

For certain embodiments, the linear transformation method can be implemented via weighting, vectorizing and so on. The calculation procedures of weighting, vectorizing, etc. and be implemented separately or at the same time. Even, the order of these calculation procedures can be adjusted.

Further, before and/or after matching at least one of the real-time magnetic value corresponding to at least one of the axis of real-time magnetic field and at least one of the reference magnetic value corresponding to at least one of the axis of reference magnetic field, further filtering at least one of the real-time magnetic value corresponding to at least one of the axis of real-time magnetic field and at least one of the reference magnetic value corresponding to at least one of the axis of reference magnetic field.

Further, matching at least one of the real-time magnetic value corresponding to at least one of the axis of real-time magnetic field and at least one of the reference magnetic value corresponding to at least one of the axis of reference magnetic field is implemented via dynamic programming algorithm, artificial intelligent algorithm, data fusion algorithm, map matching algorithm and any combination thereof.

Further, except for referring to the reference magnetic information, further detecting a plurality of non-magnetic information intermittently or continuously and directly or indirectly matching the real-time magnetic information detected and the non-magnetic information to confirm the corresponding non-magnetic information of the moving target, and the non-magnetic information is selected from pressure information, speed information, acceleration information, angle information, coordinate information, audio information, optical information, image information, radio wave information and any combination thereof.

Accordingly, directly or indirectly matching the real-time magnetic information detected and the non-magnetic information is implemented via dynamic programming algorithm, artificial intelligent algorithm, data fusion algorithm, map matching algorithm and any combination thereof.

Further, except for referring to the reference magnetic information, further referring to a plurality of reference position information intermittently or continuously and directly or indirectly matching the real-time magnetic information detected and the reference position information to confirm the corresponding reference information of the moving target, and the reference position information is selected from magnetic information, location information, coordinate information, terrain information, radio wave information and any combination thereof.

Accordingly, directly or indirectly matching the real-time magnetic information detected and the reference position information is implemented via dynamic programming algorithm, artificial intelligent algorithm, data fusion algorithm, map matching algorithm and any combination thereof.

The dynamic programming algorithms mentioned in the present invention comprise dynamic time warping (DTW) algorithm, the derivative dynamic time warping (DDTW) algorithm, etc. The artificial intelligence algorithms mentioned in the present invention comprise the Markov chain method, artificial neural networks method, decision trees method, support vector machines, regression analysis method, Bayesian networks method, Monte Carlo method, genetic algorithms, etc. The data fusion algorithms mentioned in the present invention comprise the Kalman filter, Particle filter, Bayesian filter, etc. The map matching algorithm mentioned in the present invention comprise point-to-point matching algorithm, point-to-curve matching algorithm, curve-to-curve matching algorithm, etc.

A system of magnetic positioning is suitable for positioning a moving target moving along a moving path and referring to a database storing a plurality of reference magnetic information. The reference magnetic information comprises at least a reference magnetic value of at least an axis of reference magnetic field correspondingly. The system comprises at least a magnetic detecting module and at least a calculating module. The magnetic detecting module detects a plurality of real-time magnetic information of the moving path along a moving direction of the moving target. The calculating module receives the real-time magnetic information from the magnetic detecting module and decomposes each of the real-time magnetic information according to a plurality of axes of real-time magnetic field into a plurality of real-time magnetic values. Then, the calculating module selects at least one of the real-time magnetic value corresponding to at least one of the axis of real-time magnetic field to match with the at least one of the reference magnetic values corresponding to at least one of the axes of reference magnetic field for positioning the moving target.

Further, the axes of reference magnetic field and/or the axes of real-time magnetic field are built-in axes and/or self-defined axes.

Further, at least a non-magnetic information are further stored in the database, and the calculating module directly or indirectly calibrates the real-time magnetic information and the non-magnetic information to position the moving target, and the non-magnetic information is selected from pressure information, speed information, acceleration information, angle information, coordinate information, audio information, optical information, image information, radio wave information and any combination thereof.

Further, at least a reference position information are further stored in the database, and the calculating module directly or indirectly calibrates the real-time magnetic information and the reference position information to position the moving target, and the reference position information is selected from magnetic information, location information, coordinate information, terrain information, radio wave information and any combination thereof.

Further, the reference magnetic information and the real-time magnetic information are the magnetic sensing results of geomagnetic magnetic field and non-geomagnetic magnetic field. The reference magnetic value and the real-time magnetic value are referred to the magnetic field intensity (H) and/or magnetic flux density (B).

Further, the magnetic detecting module is further selected from a geomagnetic detector, a magnetic detector (ex. single-axis magnetic detector), a 3-axis magnetic detector and any combination thereof. Wherein, the magnetic detecting module, the calculating module and the database are individual devices or integrated as a single device. Alternatively, the magnetic detecting module is installed in the moving target, and the calculating module and the database are selectively installed individually or separately in at least a device or in the moving target.

For the present invention, as amounts of the magnetic detecting module are more than one, the magnetic detecting modules are arranged according to the moving path and/or the moving direction.

Further, the moving direction of the moving target disclosed in the present invention is substantially alone a specific path including land routes, water routes and air routes. The moving target is selected from land transportations, sea transportations, air transportations and any combination thereof.

Accordingly, the method and system of magnetic positioning disclosed in the present invention overcome the technical bottleneck of the conventional technology via detecting a plurality of real-time magnetic information to match with the corresponding reference magnetic information for positioning the moving target. The present invention can make up for the lack of positioning in the highly shadowed environments in the existing positioning technologies and can also be used as an auxiliary system for other positioning technologies to improve the positioning accuracy.

### BRIEF DESCRIPTION OF THE DRAWINGS

Unless specified otherwise, the accompanying drawings illustrate aspects of the innovative subject matter described herein. Referring to the drawings, wherein like reference numerals indicate similar parts throughout the several views, several examples of heatsink fins incorporating aspects of the presently disclosed principles are illustrated by way of example, and not by way of limitation.

FIG. 1 is a flowchart of a magnetic positioning method disclosed in the present invention.

FIG. 2 is a block diagram of a magnetic positioning system disclosed in the present invention.

FIG. 3 is a schematic diagram of an embodiment of a magnetic positioning illustrated in different axial directions of the present invention.

FIG. 4 is a flowchart of a magnetic positioning method disclosed in the present invention.

FIG. 5 is a flowchart of a magnetic positioning method disclosed in the present invention.

FIG. 6A is a schematic diagram of an embodiment of magnetic positioning applied to urban roads according to the present invention.

FIG. 6B is a magnetic value diagram of each axial magnetic field detected in FIG. 6A.

FIG. 7 is a schematic diagram of the magnetic positioning of a bridge using rectangular coordinates according to the present invention, including the magnetic value of the detected axial magnetic field.

FIG. 8 is a flowchart of a magnetic positioning method disclosed in the present invention.

FIG. 9 is a flowchart of a magnetic positioning method disclosed in the present invention.

FIG. 10 is a flowchart of a magnetic positioning method disclosed in the present invention.

### DETAILED DESCRIPTION

The following describes various principles related to magnetic positioning method and system by way of reference to specific examples. More particularly, but not exclusively, such innovative principles are described in relation to selected examples and well-known functions or constructions are be described in detail for purposes of succinctness and clarity. Nonetheless, one or more of the disclosed principles can be incorporated in various other embodiments of magnetic positioning method and system to achieve any of a variety of desired outcomes, characteristics, and/or performance criteria.

Thus, the method and system disclosed having attributes that are different from those specific examples discussed herein can embody one or more of the innovative principles and can be used in applications not described herein in detail. Accordingly, embodiments of magnetic positioning not described herein in detail also fall within the scope of this disclosure, as will be appreciated by those of ordinary skill in the relevant art following a review of this disclosure.

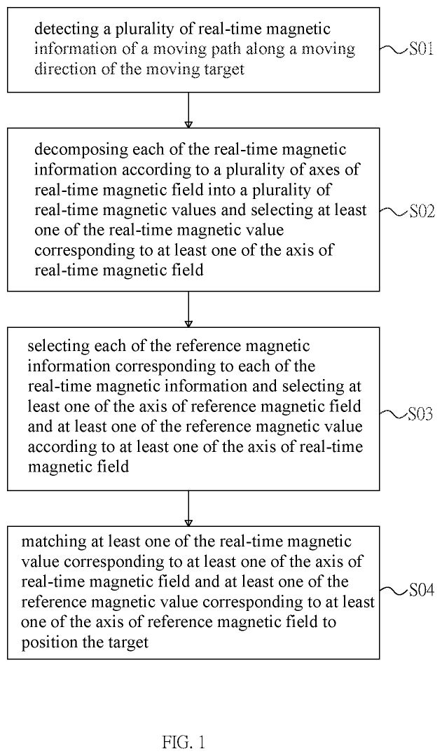

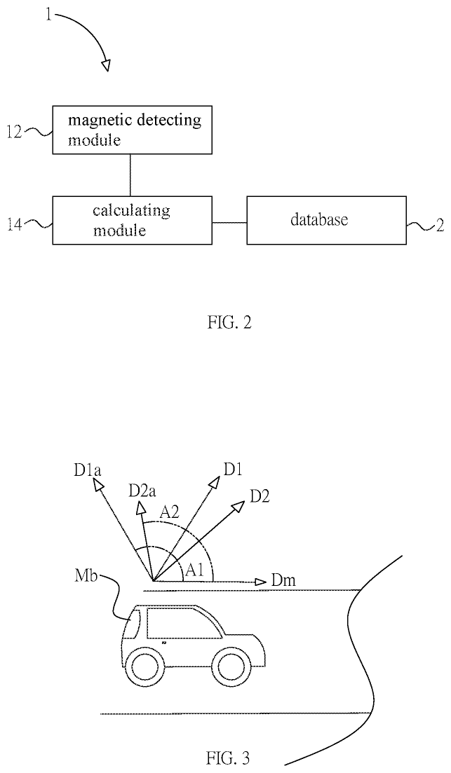

Method and system of magnetic positioning of the present invention can position a moving target. Referring to FIG. 1 and FIG. 2, the FIG. 1 is a flowchart of a magnetic positioning method disclosed in the present invention and the FIG. 2 is a block diagram of a magnetic positioning system disclosed in the present invention.

According to FIG. 1 and FIG. 2, The system of magnetic positioning 1 comprises a magnetic detecting module 12 and a calculating module 14, wherein the magnetic detecting module 12 can be one or more magnetic detector such as the magentometer, magnetic sensor and/or any sensor and detector used for detecting the magnet. In this embodiment, system of magnetic positioning 1 fetches a plurality of reference magnetic information from a database 2, wherein the reference magnetic information comprising a plurality of reference magnetic values corresponding to a plurality of axes of reference magnetic field. In detail, the method of magnetic positioning comprises the steps as follows. Firstly, in step S01, the magnetic detecting module 12 of the system of magnetic positioning 1 detects a plurality of real-time magnetic information of a moving path along a moving direction of the moving target. In step S02, the calculating module 14 decomposes each of the real-time magnetic information according to a plurality of axes of real-time magnetic field into a plurality of real-time magnetic values, and selects at least one of the real-time magnetic value corresponding to at least one of the axis of real-time magnetic field. Then, in step S03, the calculating module 14 selects each of the reference magnetic information stored in a database 2 corresponding to each of the real-time magnetic information, and selects at least one of the axis of reference magnetic field and at least one of the reference magnetic value according to at least one of the axis of real-time magnetic field; finally, in step S04, the calculating module 14 matches at least one of the real-time magnetic value corresponding to at least one of the axes of real-time magnetic field and at least one of the reference magnetic value corresponding to at least one of the axis of reference magnetic field to position the target.

In addition, in step S01, the real-time magnetic information of the moving target alone its moving direction detected via the magnetic detecting module 12 of the system of magnetic positioning 1 can be the real-time magnetic information detected at multiple time points with the same time interval, or real-time magnetic information detected at multiple time points with different time intervals. According to the detected real-time magnetic information, a set of magnetic information with unique characteristics is detected and matched with the reference magnetic information stored in the database 2. Notably, according to actual experimental results, in general, the larger the amount of real-time magnetic information detected within a certain range, the higher the accuracy of subsequent judgments and matching. The better detection quantity will be affected via the number of magnetic objects in the environment, the magnetic value of the magnetic object, the moving speed of the moving target, the sampling frequency and so on. It should be noted that detecting a plurality of real-time magnetic information of a moving path is implemented via detecting a magnetic information of all magnetic objects in an environment.

Further, the axes of reference magnetic field and/or the axes of real-time magnetic field are built-in axes and/or self-defined axes. In practical, the self-defined axes refer to the axes of the magnetic detector located (in the vehicle) at random. In some embodiments, in order to improve the accuracy of detection, the self-defined axis refers to the adjusted Z-axis vertical to the ground of the 3-axis magnetic detector. Of course, in other embodiments, the axes can refer to the built-in axes of the magnetic field stored in the database.

During the calculation and judgment process of the magnetic positioning method disclosed in the present invention, even if either the axes of reference magnetic field or the axes of real-time magnetic field is not substantially parallel to any one of axis in a Cartesian coordinate based on geomagnetism, no adjustment is required. The reason is that the theoretical basis of the magnetic positioning method disclosed in the present invention is not based on the geomagnetism for calculation or detection. According to the flowchart of a magnetic positioning method illustrated in FIG. 1, due to the reference magnetic information stored in the database 2 and the real-time magnetic information detected are all the magnetic information directly detected via the magnetic detecting module 12, the vector of either the axis of reference magnetic field or the axes of real-time magnetic field is not parallel to any orthogonal coordinate axis of the geomagnetism, the real-time magnetic value detected still can be matched with the reference magnetic value. Under certain conditions, because the reference magnetic information and real-time magnetic information may be detected via different magnetic detecting module 12, or detected via the same magnetic detecting module 12 but with different detection status, the angle (first angle) between the axis of reference magnetic field and the moving direction may not be able to keep the same with the angle (second angle) between the axes of real-time magnetic field and the moving direction during the detection period. For instance, when the first angle and the second angle are the same, it means that the vector of the axis of reference magnetic field is substantially parallel to the vector of the axis of real-time magnetic field. Still, there are two cases for the above-mentioned condition. One is that the vector of the axis of reference magnetic field is parallel and the same as the vector of the axis of real-time magnetic field. The other is that the vector of the axis of reference magnetic field is parallel but opposite to the vector of the axis of real-time magnetic field.

As amounts of the magnetic detecting module are more than one, the magnetic detecting modules are arranged according to the moving path and/or the moving direction. The magnetic detecting modules can be arranged in arbitrary, or in an array including a 1-dimensional array and a 2-dimensional array. Take the 1-dimensional array as an example, the magnetic detecting module can be arranged substantially parallel to the moving direction of the moving target. Due to the increasing amounts of the magnetic detecting modules, the positioning accuracy of the system can be improved. For example, under the condition of exerting a magnetic detecting module having a 10 Hz-sample-rate and moving at a speed of 36 km/hr, the positioning accuracy of the system can reach to 1 m. If one more magnetic detecting module having the same sample rate is arranged next to the magnetic detecting module mentioned above with a distance of 1 m, the positioning accuracy of the system can reach to 0.5 m. In this case, the positioning accuracy of the arrayed magnetic detecting modules can be equated to a single magnetic detecting module having the twice sample rate.

Take another 1-dimensional array as the example, as the magnetic detecting modules are arranged substantially vertical to the moving direction of the moving target, the positioning accuracy along the vertical direction can be improved. As the amounts along the vertical direction of the magnetic detecting modules increase, for example, a system having two 1 m-positioning-accuracy magnetic detecting modules arranged next to each other and at the line vertical to the moving direction of the moving target with a distance of 0.1 meter has 10 times of positioning accuracy comparing to the system having single 1 m-positioning-accuracy magnetic detecting module. In addition to positioning, the system having vertical array can also be used in lane deviation warning or lane change judgment.

Before matching at least one of the real-time magnetic value corresponding to at least one of the axis of real-time magnetic field and at least one of the reference magnetic value corresponding to at least one of the axis of reference magnetic field, further calibrating at least one of the axis of real-time magnetic field and at least one of the axis of reference magnetic field via linear transformation method. For certain embodiments, the linear transformation method can be implemented via weighting, vectorizing and so on. The calculation procedures of weighting, vectorizing, etc. and be implemented separately or at the same time. Even, the order of these calculation procedures can be adjusted. As an angle exists between the selected axis of real-time magnetic field and the axis of reference magnetic field corresponding to the axis of real-time magnetic field, one of the axes of magnetic field (ex. the axis of real-time magnetic field) can be linear transformed to the other axis of magnetic field (ex. the axis of reference magnetic field) referring to a space belonging to one of the axes of magnetic field (ex. the axis of reference magnetic field) before matching the axis of real-time magnetic field and the axis of reference magnetic field. Or, the axis of real-time magnetic field and the axis of reference magnetic field are both linearly transformed to a space, which is independent from the axis of real-time magnetic field and the axis of reference magnetic field. Then, match the axis of real-time magnetic field and the axis of reference magnetic field.

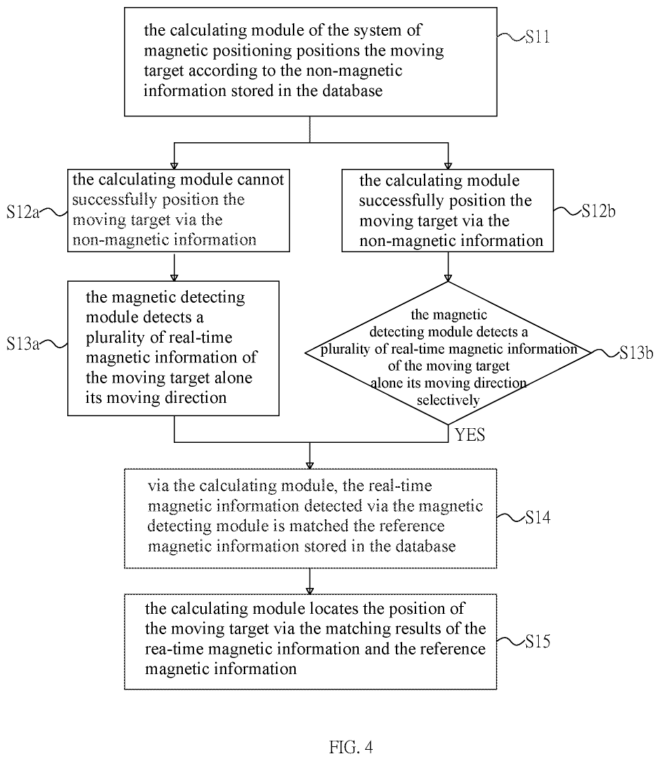

An embodiment is illustrated hereinafter. Based on the examples of the first angle A1 and the second angle A2 and referring to FIG. 1, FIG. 2 and FIG. 3, wherein FIG. 3 is a schematic diagram of an embodiment of a magnetic positioning illustrated in different axial directions of the present invention. The moving direction Dm of the moving target Mb, the vector D1 of the reference magnetic information stored in the database 2, the direction of axis D1a of reference magnetic field, the vector D2 of the real-time magnetic information detected via the magnetic detecting module 12 and the direction of axis D2a of real-time magnetic field are illustrated in FIG. 3. The first angle A1 is the angle between the direction of axis D1a of reference magnetic field and the moving direction Dm. The second angle A2 is the angle between the direction of axis D2a of real-time magnetic field and the moving direction Dm. In this embodiment, due to the vector D1 of the reference magnetic information and the direction of axis D1a of reference magnetic field are not parallel to the vector D2 of the real-time magnetic information and the direction of axis D2a of real-time magnetic field detected via the magnetic detecting module 12, in step S02, that is, when matching the real-time magnetic information with the reference magnetic information, the calculating module 14 can further match each of the real-time magnetic value corresponding to the axis of real-time magnetic field of the real-time magnetic information with each of the reference magnetic value corresponding to the axis of reference magnetic field of the reference magnetic information after adjusting at least one of the direction of axis D1a of reference magnetic field and the direction of axis D2a of real-time magnetic field according to at least one of the first angle A1 and the second angle A2. And further, the calculating module 14 can alternatively adjust the reference magnetic values of the first axis and the real-time magnetic values of the first axis. The method of adjusting mentioned above comprise angle correction, vector direction correction and so on. For instance, adjusting the direction of axis D1a of reference magnetic field substantially parallel to the direction of axis D2a of real-time magnetic field according to the first angle A1 and the second angle A2. Then, via adjusting the vector, adjusting the direction of axis D1a of reference magnetic field to have the same direction with the direction of axis D2a of real-time magnetic field. In addition, the direction of axis D1a of reference magnetic field is not limited to be vertical to the vector D1 of the reference magnetic information or the moving direction Dm; the direction of axis D2a of real-time magnetic field is not limited to be vertical to the vector D2 of the real-time magnetic information or the moving direction Dm. In other words, when the individual axis directions D1, D1a, D2, and D2a disclosed in the present invention are decomposed from a single vector into component vectors, the component vector does not necessarily need to be disassembled according to the vector decomposition method of the rectangular coordinate system or any predetermined coordinate system. Moreover, it is not necessary to disassemble the sub-vectors according to the orthogonal coordinate system of the geomagnetism or other predetermined coordinate systems in each axis direction D1, D1a, D2, D2a. In practical, in the step of matching the partial vector of the magnet value, the corresponding relationships between the axial directions D1, D1a, D2, and D2a can be referred. For example, in an embodiment, the X-axis of real-time magnetic field, Y-axis of real-time magnetic field and Z-axis of real-time magnetic field along the moving path of the moving target (such as a vehicle) can be detected via a 3-axis magnetic detector having an angle A2 corresponding to the moving direction of the moving target located inside the moving target at random, wherein the X-axis of real-time magnetic field, Y-axis of real-time magnetic field and Z-axis of real-time magnetic field are independent and perpendicular to one another. Before the matching procedure, the Z-axis of real-time magnetic field and its corresponding real-time magnetic value can be linearly transformed to the Z-axis of reference magnetic field and its corresponding reference magnetic value as the angle between the Z-axis of reference magnetic field of the reference magnetic information stored in the database 2 and the moving direction of the moving target is zero. The angles mentioned above can be detected via a gyroscope.

In practical, in the present invention, via referring to a plurality of reference position information intermittently or continuously and directly or indirectly, the reference position information can serve as the auxiliary information for predicting the position of the moving target. Further, directly or indirectly matching the real-time magnetic information detected and the reference position information is implemented via data fusion algorithm, artificial intelligent algorithm, data fusion algorithm, map matching algorithm and any combination thereof.

Further, as selecting at least one of the axis of real-time magnetic field is implemented according to a calculation of at least one of a magnitude of value, a relative variation (such as a relative magnitude of value and a variation of value) and a signal-to-noise ratio calculation of each of the real-time magnetic value corresponding to the axis of real-time magnetic field. The calculation of at least one of the magnitude of value, the relative variation (such as the relative magnitude of value and the variation of value) and the signal-to-noise ratio calculation of each of the real-time magnetic value corresponding to the axis of real-time magnetic field is one-time or continuous. For example, as the signal-to-noise ratio calculation of each of the real-time magnetic value corresponding to the axis of real-time magnetic field is one-time, and selecting the axis of real-time magnetic field with a maximum signal-to-noise ratio; as the signal-to-noise ratio calculation of each of the real-time magnetic value corresponding to the axis of real-time magnetic field is continuous, and non-adjustable or re-adjustable selecting one or more of the axis of real-time magnetic field according to the signal-to-noise ratio calculation in an order from high to low. Accordingly, during detecting through the method of magnetic positioning of the present invention, the axis of real-time magnetic field can be determined in the beginning of the method mentioned in the present invention. Or, the axis of real-time magnetic field can be changed according to the detecting results. Or, the axes of real-time magnetic field can be more than one axes according to the detecting results, and the different axes can be weighted to adjust the effects of each axis. More specifically, the real-time magnetic value corresponding to the Z-axis detected is selected to match with the reference magnetic value corresponding to the Z-axis stored in the database if the signal-to-noise ratio of the Z-axis is the highest among the signal-to-noise ratios of the X-, Y- and Z-axis as using a 3-axis magnetic detector to detect the real-time magnetic values corresponding to the X-, Y- and Z-axis. Similarly, the real-time magnetic values corresponding to the X-axis and Z-axis detected are selected to match with the reference magnetic values corresponding to the X-axis and Z-axis stored in the database if the related variation of the X-axis and Z-axis are higher than the related variation of the Y-axis.

Except for exerting the linear transformation method, in the present invention, different mathematical methods or algorithms are also used in other procedures. For example, before and/or after matching at least one of the real-time magnetic value corresponding to at least one of the axis of real-time magnetic field and at least one of the reference magnetic value corresponding to at least one of the axis of reference magnetic field, further filtering at least one of the real-time magnetic value corresponding to at least one of the axis of real-time magnetic field and at least one of the reference magnetic value corresponding to at least one of the axis of reference magnetic field. Some algorithms can be exerted for filtering the noise of signals. The algorithms comprise the linear moving average algorithm for filtering the noise of signals, the high-pass algorithm for filtering the low-frequency noise and the low-pass algorithm for filtering the high-frequency noise.

In addition, matching at least one of the real-time magnetic value corresponding to at least one of the axis of real-time magnetic field and at least one of the reference magnetic value corresponding to at least one of the axis of reference magnetic field is implemented via dynamic programming algorithm, artificial intelligent algorithm, data fusion algorithm, map matching algorithm and any combination thereof.

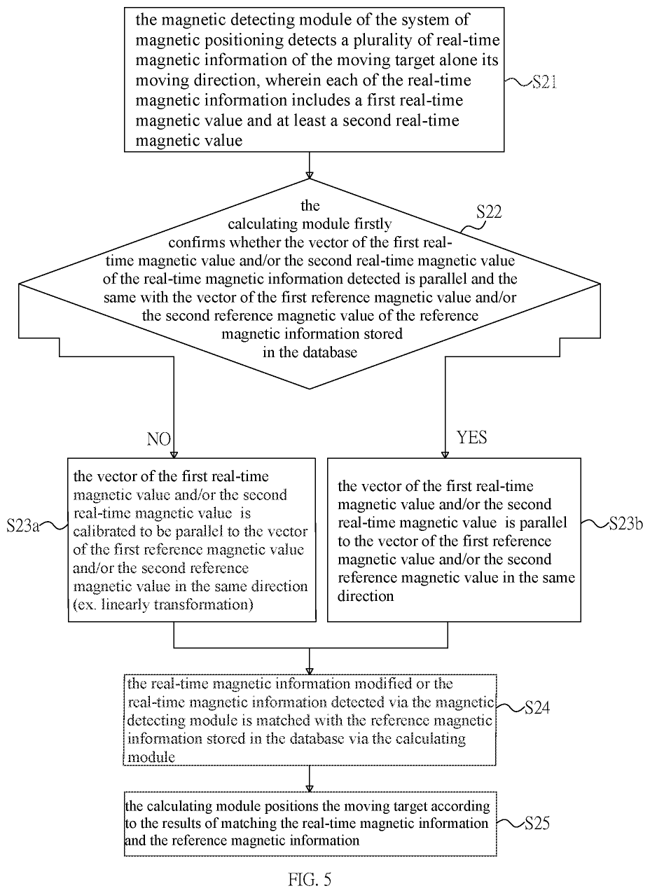

According to different requirements, such as to effectively reduce the time required for matching, improve the accuracy of positioning and so on, the magnetic positioning method disclosed in the present invention is further illustrated in FIG. 4. In FIG. 4, a flowchart of a magnetic positioning method disclosed in the present invention is illustrated. The block diagram of a magnetic positioning system, please refer to FIG. 2.

Further, except for referring to the reference magnetic information, further detecting a plurality of non-magnetic information intermittently or continuously and directly or indirectly matching the real-time magnetic information detected and the non-magnetic information to confirm the corresponding non-magnetic information of the moving target. Further, directly or indirectly matching the real-time magnetic information detected and the non-magnetic information is implemented via dynamic programming algorithm, artificial intelligent algorithm, data fusion algorithm, map matching algorithm and any combination thereof.

First, in step S11, the calculating module 14 of the system of magnetic positioning 1 positions the moving target according to the non-magnetic information stored in the database 2. In step S12a, if the calculating module 14 cannot successfully position the moving target via the non-magnetic information, execute step S13a. In step S13a, the magnetic detecting module 12 detects a plurality of real-time magnetic information of the moving target alone its moving direction. Then, in step S14, via the calculating module 14, the real-time magnetic information detected via the magnetic detecting module 12 is matched the reference magnetic information stored in the database 2. At last, in step S15, the calculating module 14 locates the position of the moving target via the matching results of the rea-time magnetic information and the reference magnetic information. Under certain conditions, after step S11, execute step S12b. In these circumstances, the calculating module 14 successfully positions the moving target via the non-magnetic information stored in the database 2. Then, execute step S13b, that is, the magnetic detecting module 12 detects a plurality of real-time magnetic information of the moving target alone its moving direction selectively. In this embodiment, execute steps S14 and S15 to continue to implement the magnetic positioning method as the step S13b is chosen to do the magnetic detecting procedure. In other situations, which is not illustrated, the magnetic positioning method may not be implemented after non-magnetic positioning method is completed. According to steps S12b and S13b mentioned above, alternatively, the magnetic detecting module 12 can further be exerted for detecting the real-time magnetic information as the calculating module 14 positions the moving target based on the non-magnetic information. In this case, not only the accuracy of the non-magnetic positioning method may be improved, but more referable magnetic information of the detected areas can be gained as well.

In the present embodiment, the details of the magnetic detecting procedures mentioned in steps of S13a S13b S14 and S15 are as illustrated in FIG. 1. For the procedures illustrated in the steps of S11, S12a to S13a and S12b to S13b, the moving path of the system of magnetic positioning 1 can be alternatively inputted via a user except detecting and determining via the calculating module 14 of the system of magnetic positioning 1. For instance, the implementation of the non-magnetic positioning method can be automatically executed via the system of magnetic positioning 1 or manually executed via the user to input a command to determine whether the non-magnetic positioning method is required. The above-mentioned situations are applicable no matter the non-magnetic positioning method is successful or failed. Notably, the commands inputted via the user can be executed through the solid components (ex. bottoms, touch panel and so on) or displayed in the command window.

The above-mentioned non-magnetic information is selected from pressure information, speed information, acceleration information, angle information, coordinate information, audio information, optical information, image information, radio wave information and any combination thereof. For instance, the position change on the moving plane of the moving target can be detected according to the acceleration changes via an accelerometer. In a practical situation, a position change of the moving target can be detected as the moving target switches from the first lane to the second lane. For other examples, as the moving target changes in height or the speed of the moving target changes dramatically, the pressure changes of the moving target can be detected via a pressure detector. Or, as the moving plane and moving direction of the moving target are non-horizontal, the tilt angle of the moving target can be detected via a tilt meter, gyroscope and so on. In practical, when the moving target is on the bridge, the tilt angle will be different from the tilt angle on the slope or on the surface of road. All the above-mentioned conditions can be used as the basis for activating the magnetic positioning method disclosed in the present invention.

Obviously, the present invention can provide an effective and accurate positioning method to assist the positioning of a moving target when other non-magnetic positioning methods fail. For an actual example, when the moving target cannot be positioned via the non-magnetic positioning method based on the global satellite navigation, the system of magnetic positioning is activated immediately for detecting the real-time magnetic information of moving target alone its moving direction. The reasons of the poor accuracy or failure of satellite navigation may due to the obstruction of three-dimensional obstacles, such as overpasses, buildings and so on.

Further, except for referring to the reference magnetic information, further referring to a plurality of reference position information intermittently or continuously and directly or indirectly matching the real-time magnetic information detected and the reference position information to confirm the corresponding reference information of the moving target, and the reference position information is selected from magnetic information, location information, coordinate information, terrain information, radio wave information and any combination thereof. For example, as the moving target moves close to a base station and receives the wireless signals from the base station, the reference magnetic information selected from the database is the magnetic information based on the signal coverage of the base station. As the moving target receives the GPS signals, the reference magnetic information selected from the database is the magnetic information based on the tolerance of GPS. As the moving target captures a certain image via the image recognition, the reference magnetic information selected from the database is the possible magnetic information within the area based on the certain image. According to the abovementioned, further match the real-time magnetic information with the reference magnetic information.

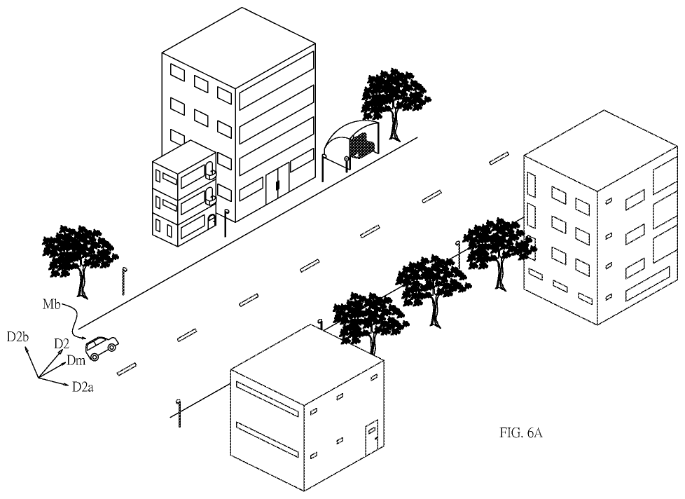

In addition, in practical applications, the vector of the real-time magnetic information detected via the magnetic detecting module is usually not parallel to the vector of the reference magnetic information stored in the database because of different installation locations or angles of the system of magnetic positioning on the moving target or fluctuation of the moving plane. Furthermore, according to the abovementioned, as selecting at least an axis of real-time magnetic field, more than one axes of real-time magnetic field can be selected. Hence, more than one real-time magnetic values can be obtained. That is, the above-mentioned real-time magnetic information comprise at least a real-time magnetic value and other real-time magnetic values corresponding to different axes of real-time magnetic field as well. The first axis of real-time magnetic field, the first real-time magnetic value, the second axis of real-time magnetic field and the second real-time magnetic value are used as examples hereinafter. Similarly, the above-mentioned reference magnetic information comprises at least a reference magnetic value and other reference magnetic values corresponding to different axes of reference magnetic field as well. The first axis of reference magnetic field, the first reference magnetic value, the second axis of reference magnetic field and the second reference magnetic value are used as examples hereinafter. Notably, no matter for the real-time magnetic information or the reference magnetic information, generally, the first axis of real-time magnetic field, the second axis of real-time magnetic field and other further axis of real-time magnetic field are perpendicular to one another in the space (ex. 3-D space); similarly, the first axis of reference magnetic field, the second axis of reference magnetic field and other further axis of reference magnetic field are perpendicular to one another in the space (ex. 3-D space). Hence, the conditions of the vectors of the first axis and second axis of the real-time magnetic field are not parallel to the vectors of the first axis and the second axis of the reference magnetic field can be describe as that the vector of the real-time magnetic information is not parallel to the vector of the reference magnetic information. And under most of the conditions, for instance, when the moving target moves between multi-layered bridges, or when constructing buildings and bridges, the steel beams and steel bars are additionally given an external electric field, stress, or heat to generate magnetism, the magnetism is arranged arbitrarily. Moreover, because the vectors of the magnetic of the magnetic objects may not be consistent with the vector of the geomagnetism, the vectors of the magnetic between different magnetic objects may not be consistent, or the detecting angles of the reference magnetic information and the real-time magnetic information are different, the vector of the first axis of the real-time magnetic field is opposite to or not parallel to the vector of the first axis of the reference magnetic field. The above-mentioned condition is illustrated in FIG. 5. In FIG. 5, a flowchart of a magnetic positioning method disclosed in the present invention is illustrated. The block diagram of a magnetic positioning system, please refer to FIG. 2.

First, in step S21, the magnetic detecting module 12 of the system of magnetic positioning 1 detects a plurality of real-time magnetic information of the moving target alone its moving direction, wherein each of the real-time magnetic information includes a first real-time magnetic value of the first axis of real-time magnetic field and at least a second real-time magnetic value of the second axis of real-time magnetic field. In step S22, the calculating module 14 firstly confirms whether the first axis of real-time magnetic field and/or the second axis of real-time magnetic field of the real-time magnetic information detected is parallel and the same with the first axis of reference magnetic field and/or the second axis of reference magnetic field of the reference magnetic information stored in the database 2. If the first axis of real-time magnetic field and/or the second axis of real-time magnetic field of the real-time magnetic information is not parallel or different from the first axis of reference magnetic field and/or the second axis of reference magnetic field of the reference magnetic information, then execute step S23a; oppositely, if the first axis of real-time magnetic field and/or the second axis of real-time magnetic field of the real-time magnetic information is parallel and the same with the first axis of reference magnetic field and/or the second axis of reference magnetic field of the reference magnetic information, then execute step S23b. In step S23a, the first axis of real-time magnetic field and/or the second axis of real-time magnetic field of the real-time magnetic information is corrected to be parallel to the first axis of reference magnetic field and/or the second axis of reference magnetic field of the reference magnetic information and has the same direction of the first axis of reference magnetic field and/or the second axis of reference magnetic field of the reference magnetic information via the calculating module 14 executing any kinds of calculation, simulation and so on, such as coordinate transformation. After steps S23a and S23b, in step S24, the real-time magnetic information (as illustrated in step S23a) modified or the real-time magnetic information detected via the magnetic detecting module 12 is matched with the reference magnetic information stored in the database 2 via the calculating module 14. Finally, in step S25, the calculating module 14 positions the moving target according to the results of matching the real-time magnetic information and the reference magnetic information.

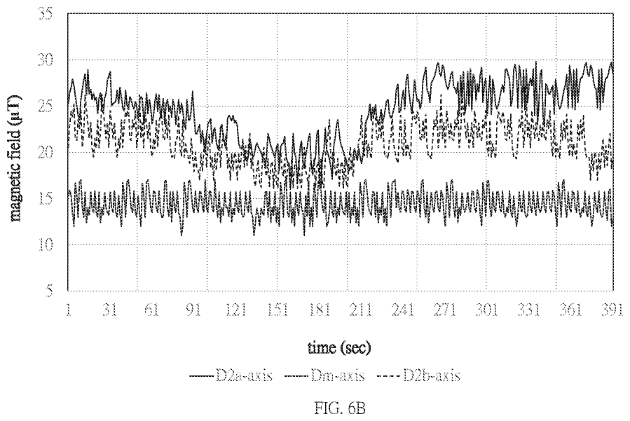

In environments with multiple sources of magnet, such as cities with many buildings, complex structures, buildings with staggered steel beams and so on, except for the effects of the first real-time magnetic value of the first axis of real-time magnetic field, the effects of the second real-time magnetic value of the second axis of real-time magnetic field cannot be ignore either. For instance, as illustrated in FIG. 6A and FIG. 6B. FIG. 6A is a schematic diagram of an embodiment of magnetic positioning applied to the moving target Mb moving on urban roads according to the present invention and FIG. 6B is a magnetic value diagram of each axial magnetic field detected in FIG. 6A. In the embodiment, the moving target Mb moves alone the moving direction Dm. Comparing to the magnetic changes of the moving direction Dm, the most significant magnetic change occurs in the vector of the first axis of real-time magnetic field D2a of the real-time magnetic value decomposed from the vector of the magnetic information D2. Not as obvious as the magnetic change of the vector of the first axis of real-time magnetic field D2a of the real-time magnetic value, the magnetic change the vector of the second axis of real-time magnetic field D2b of the real-time magnetic value is observable. It is because that there are many magnetic objects such as buildings, street lamps, electric poles, and so on along the moving direction Dm of the moving target Mb, so the magnetic changes of the first axis of real-time magnetic field D2a of the real-time magnetic value and the second axis of real-time magnetic field D2b of the real-time magnetic value are significant. Of course, the magnetic change occurs alone the moving direction Dm. However, according to the FIG. 6B, the magnetic change occurs alone the moving direction Dm is insignificant so that the magnetic change can be ignored as matching. Under certain conditions or requirements, the magnetic change in the moving direction Dm can still be used as one of the basis for matching.

As detecting the real-time magnetic information of the moving path, the magnetic information of all magnetic objects in the environment is detected. Accordingly, different from the lanes in ordinary urban areas, except for the magnetic objects such as streets and fences constructed on the bridge surface, the structure of the bridge itself contains a large number of magnetic objects, such as steel bars, cables, bars and so on. These magnetic objects are respectively corresponding to the pier, steel cable, fence and other structures of the bridge. Thus, the magnetic changes on the bridge is quite significant.

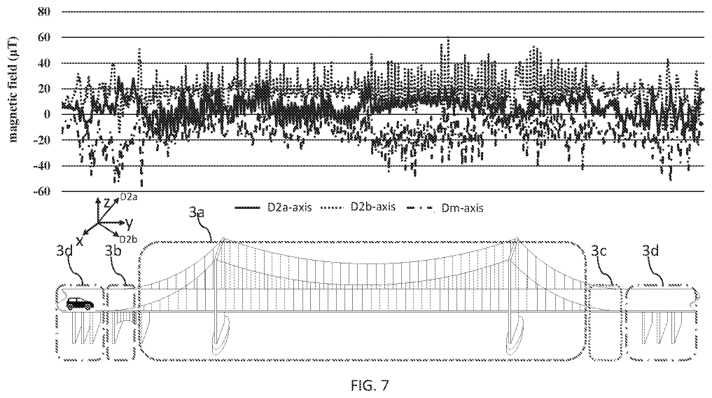

According to the actual detecting results, referring to the FIG. 7. illustrating a schematic diagram of the magnetic positioning of a bridge using Cartesian coordinates according to the present invention, including the magnetic value of the detected axial magnetic field. The bridge disclosed in this embodiment is a suspension-designed main body 3a (short dashed line section) having arch side 3b (long dashed section), side 3c (dotted line) with less structure, end 3d (long and short dashed lines) having the simply supported structure. Hence, within the main body 3a section, because the suspension cable is distributed fairly uniformed, the magnetic changes due to the magnetism of the steel cable alone the moving direction Dm, the axis of the real-time magnetic field D2a, and the axis of the real-time magnetic field D2b are illustrated regularly. In the area of side 3b, the magnetic changes are more significant with the design of the arch and the influence of the additional buildings below. In the area of the other side 3c, the magnetic changes are insignificant due to no dense rigid structure within the area. The trusses in the area of the two ends 3d of the bridge have a large amount of steel bars arranged therein, so that obvious and prominent magnetic changes can be detected at the pillars corresponding to the trusses. From what illustrated in FIG. 6 and FIG. 7, due to the presence of a large number of magnetic objects in the environment, the magnetic changes is quite significant, so that each of the magnetic changes of the real-time magnetic information detected at various positions has its own unique characteristics. Therefore, unique characteristics of the magnetic changes of the real-time magnetic information can be applied not only to position the moving target, but to precisely trace the moving target on a specific lane of a road or bridge.

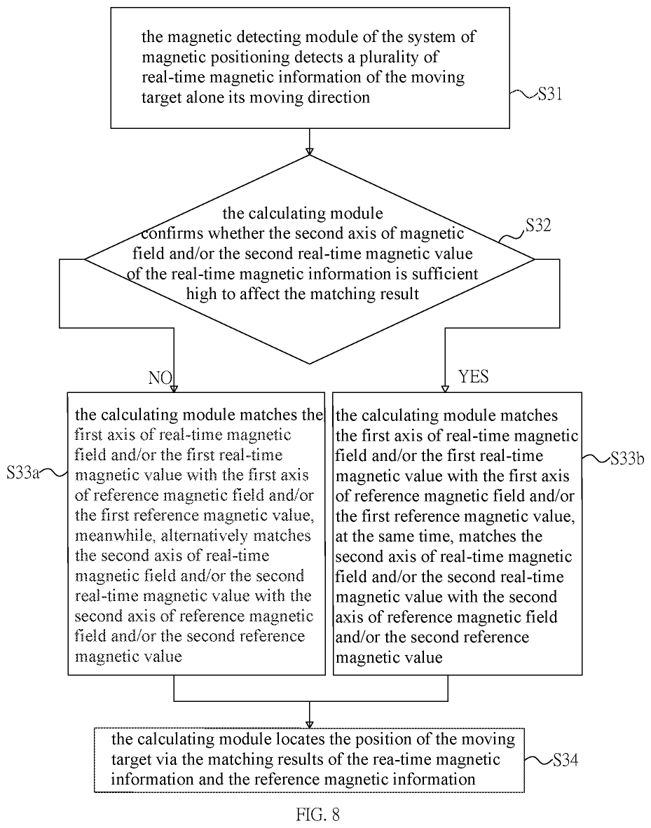

Under the similar condition mentioned above, a flowchart of a magnetic positioning method disclosed in the present invention is illustrated in FIG. 8. The block diagram of a magnetic positioning system, please refer to FIG. 2.

First, in step S31, the magnetic detecting module 12 of the system of magnetic positioning 1 detects a plurality of real-time magnetic information of the moving target alone its moving direction, wherein each of the real-time magnetic information includes a first real-time magnetic value of a first axis of real-time magnetic field and at least a second real-time magnetic value of at least a second axis of real-time magnetic field. In step S32, the calculating module 14 confirms whether the second real-time magnetic value of the second axis of real-time magnetic field of the real-time magnetic information is sufficient high to affect the matching result, wherein the basis of the confirmation comprises confirming a magnitude of value, a relative variation (such as a relative magnitude of value and a variation of value) and/or the signal-to-noise ratio of the second real-time magnetic value of the second axis of real-time magnetic field, or confirming the ratio of the second real-time magnetic value of the second axis of real-time magnetic field to the first real-time magnetic value of the first axis of real-time magnetic field, or confirming whether a requirement of the second real-time magnetic value of the second axis of real-time magnetic field directly input from the external and so on. If no, execute step S33a; if yes, execute step S33b. In step S33a, the calculating module 14 selects the first real-time magnetic value corresponding to the first axis of real-time magnetic field of the real-time magnetic information with the first reference magnetic value corresponding to the first axis of reference magnetic field of the reference magnetic information stored in the database 2, meanwhile, alternatively matches the second real-time magnetic value corresponding to the second axis of real-time magnetic field of the real-time magnetic information with the second reference magnetic value corresponding to the second axis of reference magnetic field of the reference magnetic information stored in the database 2. In step S33b, the calculating module 14 matches the first real-time magnetic value corresponding to the first axis of real-time magnetic field of the real-time magnetic information with the first reference magnetic value corresponding to the first axis of reference magnetic field of the reference magnetic information stored in the database 2, meanwhile, matches the second real-time magnetic value corresponding to the second axis of real-time magnetic field of the real-time magnetic information with the second reference magnetic value corresponding to the second axis of reference magnetic field of the reference magnetic information stored in the database 2. At last, in step S34, according to the result of abovementioned steps, the calculating module 14 locates the position of the moving target via the matching results of the first axis of real-time magnetic value corresponding to the first axis of real-time magnetic field and/or the second axis of real-time magnetic value corresponding to the second axis of real-time magnetic field of the real-time magnetic information detected and the first axis of reference magnetic value corresponding to the first axis of reference magnetic field and/or the second axis of reference magnetic value corresponding to the second axis of reference magnetic field of the reference magnetic information stored in the database 2. In this embodiment, the method of magnetic positioning is mainly based on the original magnetic value detected via the magnetic detecting module 12, that is, in the procedure of positioning via the magnetic value, the basis of calculation is the magnetic value of the single axis detected via the magnetic detecting module 12. In addition, in the step S34, except for based on the criteria of the magnitude of value, the relative variation (such as the relative magnitude of value and the variation of value) and/or the signal-to-noise ratio of the real-time magnetic value, the calculating module 14 can selectively select at least a real-time magnetic field and its corresponding real-time magnetic value for matching further based on the linearly-transformed axis of the magnetic field as illustrated in FIG. 5.

Obviously, comparing to the method and system of the present invention, the magnetic value of a single axis cannot be detected due to the conventional magnetic detection devices (such as compasses) is used. For instance, when a vehicle passes by a bridge, due to the influence of steel bars, steel cables, or other magnetic objects inside or outside the bridge, the geomagnetic data detected via the conventional magnetic detection device is affected because of the magnetic field of the bridge itself. Hence, the direction of the magnetic pole detected via the magnetic detection device would be misjudged due to the offset of the magnetic pole. However, in the method of magnetic positioning disclosed in the present invention, in addition to detect the magnetic value of a single axis, further determine the directions of the source magnetic objects and the influence of magnetic values in different axes on the overall magnetic field. In addition to the first real-time magnetic value corresponding to the first axis of real-time magnetic field, the second real-time magnetic value corresponding to the second axis of real-time magnetic field is selectively considered for matching. Thus, no matter the magnetic field distribution is simple or complicated, several magnetic values of the corresponding single axis detected can meet the demands of most of the characteristics and requirements of various environments. Further, via matching several magnetic values of different axes, the accuracy of the method of magnetic positioning can be greatly improved.

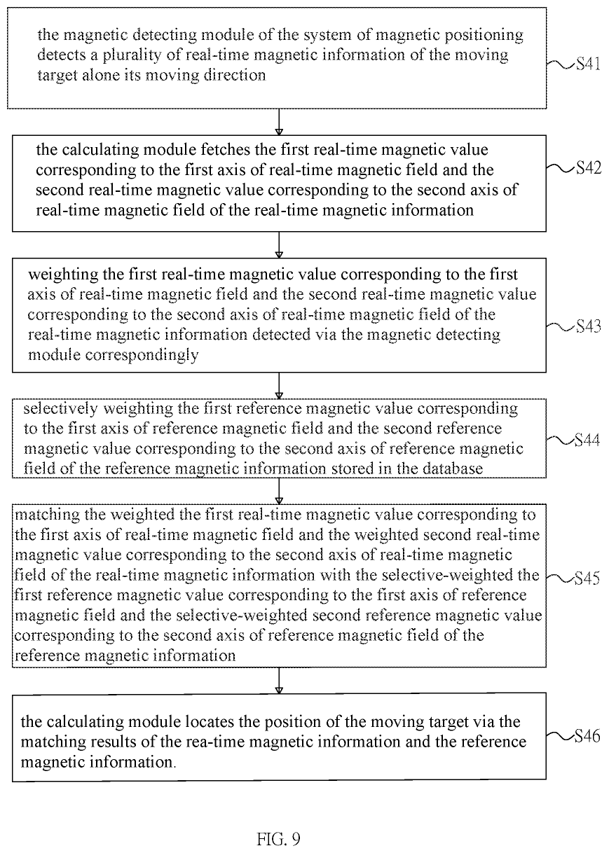

Please referring to FIG. 2 and FIG. 9. Hereinafter, an embodiment of weighting a magnetic value of a specific axis is disclosed. First, in step S41, the magnetic detecting module 12 of the system of magnetic positioning 1 detects a plurality of real-time magnetic information of the moving target alone its moving direction, wherein each of the real-time magnetic information includes a first real-time magnetic value corresponding to a first axis of real-time magnetic field and at least a second real-time magnetic value corresponding to at least a second axis of real-time magnetic field. Then, in step S42, the calculating module 14 fetches the first real-time magnetic value corresponding to the first axis of real-time magnetic field and the second real-time magnetic value corresponding to the second axis of real-time magnetic field of the real-time magnetic information. In step S43, according to the environment and demand, weighting the first real-time magnetic value corresponding to the first axis of real-time magnetic field and the second real-time magnetic value corresponding to the second axis of real-time magnetic field of the real-time magnetic information detected via the magnetic detecting module 12 correspondingly. In step S44, selectively weighting the first reference magnetic value corresponding to the first axis of reference magnetic field and the second reference magnetic value corresponding to the second axis of reference magnetic field of the reference magnetic information stored in the database 2. In step S45, matching the weighted the first real-time magnetic value corresponding to the first axis of real-time magnetic field and the weighted second real-time magnetic value corresponding to the second axis of real-time magnetic field of the real-time magnetic information with the selective-weighted the first reference magnetic value corresponding to the first axis of reference magnetic field and the selective-weighted second reference magnetic value corresponding to the second axis of reference magnetic field of the reference magnetic information. At last, in step S46, the calculating module 14 locates the position of the moving target via the matching results of the weighted the first real-time magnetic value corresponding to the first axis of real-time magnetic field and the weighted second real-time magnetic value corresponding to the second axis of real-time magnetic field of the real-time magnetic information with the selective-weighted the first reference magnetic value corresponding to the first axis of reference magnetic field and the selective-weighted second reference magnetic value corresponding to the second axis of reference magnetic field of the reference magnetic information. Wherein, the real-time magnetic value for weighting is determined based on each of the axes of real-time magnetic field and/or each of the real-time magnetic values. For example, the real-time magnetic values and the axes of real-time magnetic field thereof can be selected via comparing the differences of the magnitude of value, the relative variation (such as the relative magnitude of value and the variation of value) and/or the signal-to-noise ratio.

The above-mentioned method is based on the premise of confirming that the second real-time magnetic value of the real-time magnetic information to weight the first real-time magnetic value corresponding to the first axis of real-time magnetic field and the second real-time magnetic value corresponding to the second axis of real-time magnetic field of the real-time magnetic information at the same time under different conditions of environmental demands. The weighted percentage of the second real-time magnetic value corresponding to the second axis of real-time magnetic field of the real-time magnetic information and the weighted percentage of the first real-time magnetic value corresponding to the first axis of real-time magnetic field can be the same or be different. For instance, under certain conditions, the influence of the weighted second real-time magnetic value corresponding to the second axis of real-time magnetic field of the real-time magnetic information almost be the same with the influence of the non-weighted first real-time magnetic value corresponding to the first axis of real-time magnetic field of the real-time magnetic information. Hence, the weighted percentage of the first real-time magnetic value corresponding to the first axis of real-time magnetic field of the real-time magnetic information and the weighted percentage of the first reference magnetic value corresponding to the first axis of reference magnetic field can be the same or be different; the weighted percentage of the second real-time magnetic value corresponding to the second axis of real-time magnetic field of the real-time magnetic information and the weighted percentage of the second reference magnetic value corresponding to the second axis of reference magnetic field can be the same or be different. In addition, the first reference magnetic value corresponding to the first axis of reference magnetic field and the second reference magnetic value corresponding to the second axis of reference magnetic field of the reference magnetic information can be selectively weighted as at least one of the first real-time magnetic value corresponding to the first axis of real-time magnetic field and the second real-time magnetic value corresponding to the second axis of real-time magnetic field of the real-time magnetic information is required to be weighted.

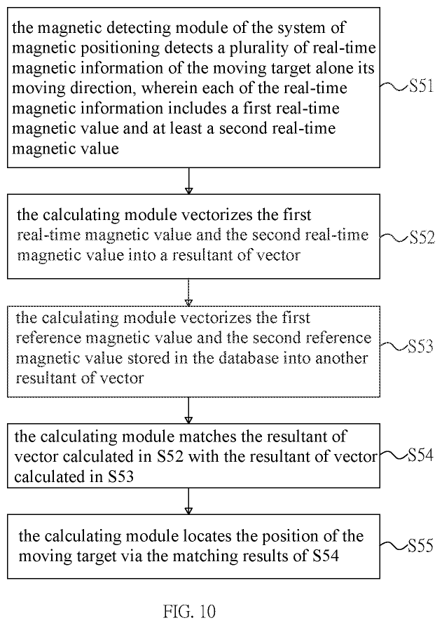

Unlike the matching bases of the above-mentioned embodiment are the original magnetic information, an embodiment of vectorized magnetic values of single axis is disclosed hereinafter. Please referring to FIG. 2 and FIG. 10. In step S51, the magnetic detecting module 12 of the system of magnetic positioning 1 detects a plurality of real-time magnetic information of the moving target alone its moving direction, wherein each of the real-time magnetic information includes a first real-time magnetic value of the first axis of real-time magnetic field and at least a second real-time magnetic value of the second axis of real-time magnetic field. Then, in step S52, the calculating module 14 vectorizes the first real-time magnetic value of the first axis of real-time magnetic field and the second real-time magnetic value of the second axis of real-time magnetic field into a resultant of vector. In step S53, the calculating module 14 vectorizes the first reference magnetic value of the first axis of reference magnetic field and the second reference magnetic value of the second axis of reference magnetic field stored in the database 2 into another resultant of vector. In step S54, the calculating module 14 matches the resultant of vector calculated in S52 with the resultant of vector calculated in S53. At last, in step S55, the calculating module 14 locates the position of the moving target via the matching results of S54. Before the steps S52 and S53, the calculating module 14 further selectively weights the real-time magnetic information (first real-time magnetic value and/or the second real-time magnetic value) and the reference magnetic information (first reference magnetic value and/or the second reference magnetic value) as illustrated in FIG. 9. In precise, the calculating module 14 may selectively weight the first real-time magnetic value, the second real-time magnetic value, first reference magnetic value and the second reference magnetic value and then vectorizes the first axis of real-time magnetic field, the second axis of real-time magnetic field, the first axis of reference magnetic field and the second axis of reference magnetic field if necessary.

According to the FIG. 8, FIG. 9 and FIG. 10, the method for determining the significances of the axes of magnetic field can further be implemented via the A1 algorithms except for calculating of the magnitude of value, the relative variation (such as the relative magnitude of value and the variation of value), the signal-to-noise ratio, etc. Also, the weighting method illustrated in FIG. 9 can be an alternative way to determining the significances of the axes of magnetic field. For example, as one of the weighting coefficient of the axis of magnetic field is much smaller than rest of the weighting coefficients of the axes of magnetic field, the axis of magnetic field and the corresponding magnetic value with the smallest coefficient can be selectively excluded when processing the calculation of the method mentioned in the present invention. For some certain embodiments, the effect of the axis of magnetic field having the smallest correspondent magnetic value may be minimized or eve excluded after the calculation of vectorization illustrated in FIG. 10. Additionally, as more than one axes of magnetic field and/or more than one magnetic values are required for calculation of the magnetic position method of the present invention, accordingly, the procedures of weighting and vectorizing for calculating the axes of magnetic field and/or the magnetic values can be implemented selectively and in different order. For example, the above-mentioned procedures can be used interactively in practical applications. For instance, for the system of magnetic positioning of the present invention, in addition to the first real-time magnetic value, the second real-time magnetic value and non-magnetic information can be further taken into calculation. Furthermore, the second real-time magnetic value and/or the second reference magnetic value of the real-time magnetic information and the reference magnetic information can selectively be weighted. According to the information stored in the database or other reasons, the original magnetic information, the weighted magnetic information and the vectorized magnetic information can be exerted for matching.

Comparing to the conventional resultant of vector directly calculated via geomagnetism and ambient magnetic field, the magnetic values can be weighted and/or vectorized based on different axes of the magnetic values according to the environment or demands. Hence, the method and system of magnetic positioning can be implemented to the conventional non-magnetic positioning method. Furthermore, the method of the present invention improves the accuracy of positioning via emphasizing the magnetic characteristics of each area for identification and specification via weighting the magnetic values of all axes especially as the area is highly three-dimensional sheltered. In fact, the method processing the magnetic values of all axes of magnetic information is not completely revealed in any other conventional positioning method.

The dynamic programming algorithms and/or artificial intelligence algorithms and/or the data fusion algorithms and/or map matching algorithm are exerted to deal with the calculations of match the real-time magnetic information with the reference magnetic information, wherein the dynamic programming algorithms include the dynamic time warping (DTW) algorithm, the derivative dynamic time warping (DDTW) algorithm, etc. and the artificial intelligence algorithms include the Markov chain method, artificial neural networks method, decision trees method, support vector machines, regression analysis method, Bayesian networks method, Monte Carlo method, genetic algorithms, etc. The filtering algorithms include Kalman filtering algorithm, particle filtering algorithm, Bayesian filtering algorithm, etc. The map matching algorithms include point-to-point matching algorithm, point-to-curve matching algorithm, curve-to-curve matching algorithm, etc.

Using the dynamic time warping (DTW) algorithm as an example, according to the location of the moving target, the magnetic information detected is defined as sequence Q (query) having a length m and the corresponding map information is defined as sequence R (reference) having a length n. Differential the sequence Q and sequence R to obtain the differential sequence Q′ and the differential sequence R′ having the length m′ (m−2) and the length n′ (n−2) correspondingly. Then, an Equation (1) can be obtained:

$${D}_{\text{?}} [ q ] = \frac{( {q}_{i} - {q}_{i - 1} ) + ( ( {q}_{i + 1} - {q}_{i - 1} ) / 2 )}{2} \\ 1 < i < m \\ \text{?} \text{indicates text missing or illegible when filed} \qquad Equation ( 1 )$$

Create a matrix of distance D having a size of m′*n′, wherein the matrix element (i,j) represent the distance between the point of Q′i and the point of P′j and the distance between the point of Q′i and the point of P′j can be revealed as following:

d(Q′i,R′j)=|Q′i−R′j|2

Further, create a matrix of cumulative distance C having a size of m′*n′ and the cumulative distance can be revealed as following:

C(i,j)=d(Q′i,R′j)+min{C(i−1,j),C(i−1,j−1),C(i−1,j−2)}

Finally, via defining the patterns of paths, backtrack the best path to confirm the corresponding relationship between the magnetic information and the map information from the smallest element in the last column of the matrix of cumulative distance C and eventually position the moving target.

Further, using the artificial intelligence algorithm as another example. First, provide and filter the magnetic information via the pre-treatment. Exert the filtered magnetic information as the training data of the artificial intelligence algorithm such as Markov chain algorithm. Hence, as at least a new real-time magnetic information is detected, the corresponding map information of the real-time magnetic information can be determined to position the moving target.

Wherein, the artificial intelligence algorithms include the Markov chain method, artificial neural networks method, decision trees method, support vector machines, regression analysis method, Bayesian networks method, Monte Carlo method, genetic algorithms, etc.

Take the data fusion algorithm as an example, the next location of the moving target having a linear motion model can be predicted via the Kalman filtering algorithm. Further, the real-time magnetic information is detected via the magnetic detecting module along the moving path (ex. the road section) for matching with the reference magnetic information from the database to position the moving target. Based on the error of positioning obtained from the calculation of prediction and detection of the real-time magnetic information, the moving target is repeatedly re-positioned via the recursive calculation.

In order to improve the accuracy of positioning, the magnetic values of the single axis can be further performing noise filtering including the moving average method, high- or low-pass filtering method, band-pass filtering method, band-stop filtering method and so on. In some cases, other detectors can be exerted to remove unreasonable values or outliers.

As mentioned above, the reference magnetic information and the real-time magnetic information are the magnetic sensing results of geomagnetic magnetic field and fixed-object magnetic field. Wherein, all the real-time magnetic value and reference magnetic value comprise at least one of magnetic field intensity (H) and magnetic flux density (B). The magnetic detecting module, the calculating module and the database are individual devices or integrated as a single device. Alternatively, the magnetic detecting module is installed in the moving target, and the calculating module and the database are selectively installed in the moving target or any other devices such as a base station, a cloud database and so on. The magnetic detecting module is further selected from a geomagnetic detector, a magnetic detector (ex. single-axis magnetic detector), a 3-axis magnetic detector and any combination thereof.

Different from the conventional satellite, image and other methods for positioning, the real-time, specific detection of the magnetic information are detected for positioning in the present invention. In other words, as long as the magnetic information of the position can be detected, the magnetic positioning method of the present invention can be used for positioning. Hence, the difficulties of positioning caused by any three-dimensional obstacle and the weather issue are eliminated.

More precisely, except for the geomagnetism, the magnetic values of the single axis of the magnetic information detected further comprise the magnetic information generated via magnetic objects in structures such as existing fixed buildings, utility poles, and bridge structures in the environment and so on. The magnetic objects include such as, but not limited to, steel bars, metal materials and so on. The magnetic information not only can be used to position a moving object on a level road but also to detect the moving object has a change in road level. In practical, the magnetic field positioning method of the present invention can provide a wider area and finer positioning capabilities. For instance, the high density of the magnetic information can be constructed according to the piers, slings and bridge reinforcement to accurately position the vehicle moving on the bridge at different locations. According to the actual detection results, the magnetic positioning method disclosed in the present invention can not only locate the vehicle on a road or bridge, but also use one or more magnetic information of each lane that are substantially perpendicular to the direction of trace of the vehicle to accurately identify vehicles on specific lanes of roads or bridges. With the high density of magnetic information, that is, the variety of magnetic information in unit length is significant, the accuracy of positioning can be greatly improved. And similarly, the high accuracy of positioning can be obtained as exerting the method of the present invention for the area of high building density or even indoor. Obviously, different from the conventional compass positioning technology, the position and the moving status of the moving target can be detected via distinguishing the characteristics of the real-time magnetic information of the environment, especially the characteristics of the real-time magnetic values of the first axis of the real-time magnetic information. Accordingly, due to this feature, the present invention is particularly suitable for applications in areas with specific and fixed magnetic field characteristics. In other words, the moving direction of the moving target is substantially alone a specific path. The specific path mentioned includes land routes, water routes and air routes. Within a certain range around the specific path, usually, a plurality of facilities having the fixed magnetic information characteristics are established. For instance, the magnetic information of the fixed facilities such as the buildings, lamp posts, electric poles, bridges, etc. around the land routes form a specific magnetic information characteristics against the specific section of the land route and/or of the lane. Since the density and magnetic value of these facilities reveal magnetic information in a particular axis obviously, in the present invention, the efficiency of the positioning method can be achieved by matching the real-time magnetic values of the first axis of the real-time magnetic information and the reference magnetic values of the first axis of the reference magnetic information.

For example, in the application of land routes according to the present invention, the magnetic information can be collected via the magnetic detecting equipment such as measuring vehicle and further uploaded to user's device and/or the cloud. Through the linear algebra algorithms and/or artificial intelligence algorithms, the magnetic information can be matched with the map information. As exerting different algorithms or under different conditions, extra detectors can be exerted or the pre-filtering and/or the post-filtering methods might be required to integrate the results of different axes.

As for the applications of air routes, the magnetic information detected in the air mainly comes from geomagnetism. Hence, the heterogeneity of geomagnetism on the earth can be exerted to determine the magnetic information in the air. During the flight of the aircraft (ex. airplane), the magnetic information correspondingly changes with different flight altitudes and different flight attitudes. The change of the flight attitude can be calibrated according to the linear mapping transform coordinate space. For example, as the head of the aircraft is raised to 90 degree for climbing, the original Y-axis is mapped as a new Z-axis and the original Z-axis is mapped as a new Y-axis with an opposite vector.

As for the applications of water routes, the position method may be divided into two cases: below sea level and at sea level. The method at sea level substantially is similar to the method applied for the air routes. However, at sea level, changes in altitude can be ignored. The effects of waves can be corrected by gyroscopes and accelerometers. The method below sea level can be suitable for applications such as divers, submarines, etc. Under these conditions, the users (ex. divers, submarines) are located closer to the seabed, reef rocks, trenches, etc., the magnetic information of crustal iron ore, shipwrecks and other objects can be detected as the reference for positioning. The changes of the attitude of the users can be calibrated in the same way described in the above paragraph for the air routes.

As positioning a vehicle, when the vehicle moves on existing roads and bridges marked on the map, that is, moves on an existing path, the real-time magnetic information of the vehicle around the path can be detected via the magnetic detecting module. The real-time magnetic information comprises the real-time magnetic values of the first axis and the real-time magnetic values of the second axis. The magnetic detecting module can be a magnetic detector in a smart phone, or any commercially available multi-axis magnetic detector. The real-time magnetic information from the magnetic detecting module would be matched with the reference magnetic information storied in the database via the calculating module. According to the matching result, the vehicle can be positioned on the inside, middle, or outside lane of the path.

For the present invention, the magnetic information likes magnetic values of a specific axis are mainly detected when a moving target is moving along a path. That is, detect and collect the real-time magnetic information continuously as the moving target moves along the moving direction within a certain time interval, from a first position to a second position. Further, match the detected real-time magnetic information, the stored reference magnetic information with the corresponding time intervals to judge whether the vehicle changes the lanes on the path. For instance, if the real-time magnetic information between the first time point and the second time point are corresponding to the reference magnetic information of different sections on the first lane, and the real-time magnetic information detected after the second time point cannot be in any reference magnetic field information corresponding to the first lane but is referred magnetic field information corresponding to a segment on the second lane, the moving target changes lane after second point. The magnetic information comprises at least one of the original magnetic value of single axis, the weighted magnetic information and the vectorized magnetic information, wherein the weighted and the vectorized calculation can be done selectively.

When positioning a transportation, a non-magnetic detecting module can also be used for limiting the area where the transportation is located. The non-magnetic detecting module comprises a base station, small cell, access point, global positioning system, global satellite navigation system, radar system, or any non-magnetic detection system. For instance, when the calculating module matches the 5G information in the database after connecting and receiving attached signals from a 5G base station, the track area of the vehicle can be limited so that the accuracy of positioning can be improved via minimized the matching range of the database and shortened the processing time. For the present invention, the better embodiments of the moving target can be selected from land transportations, sea transportations, air transportations and any combination thereof.

According to the experimental results, different procedures can be used for processing the original magnetic information because the directions of the axes of the magnetic field of the geomagnetism and the fixed magnetic objects are different. For instance, when a vehicle or a pedestrian is moving, comparing to the magnetic value of the first axis and/or the second axis, the changes of the magnetic information alone the moving direction is insignificant. Therefore, when performing weighted calculations, magnetic information in specific axes can be more weighted to improve the accuracy of positioning. Moreover, continuous magnetic information within a period of time or along the moving path can be measured and matched for more accurate positioning.

The present invention can be further applied to pedestrian positioning. A detector (ex. acceleration detectors, gyroscopes) is required which is often mounted on a smart phone. Take the gyroscope as an example, the inclination of a pedestrian and the ground plane can be detected via the gyroscope and then the magnetic information of the three axes can be transformed to reference axes. Finally, the real-time magnetic information can be matched with the reference magnetic information for the pedestrian positioning.

The method and system of magnetic positioning of the present invention overcome the technical bottlenecks in the prior art via detecting magnetic information and performing magnetic information matching. Different to wireless positioning method such as GPS Wi-Fi, the positioning accuracy of the method and system would not be affected by weather and obstacles.

The presently disclosed inventive concepts are not intended to be limited to the embodiments shown herein, but are to be accorded their full scope consistent with the principles underlying the disclosed concepts herein. Directions and references to an element, such as “up,” “down,”, “upper,” “lower,” “horizontal,” “vertical,” “left,” “right,” and the like, do not imply absolute relationships, positions, and/or orientations. Terms of an element, such as “first” and “second” are not literal, but, distinguishing terms. As used herein, terms “comprises” or “comprising” encompass the notions of “including” and “having” and specify the presence of elements, operations, and/or groups or combinations thereof and do not imply preclusion of the presence or addition of one or more other elements, operations and/or groups or combinations thereof. Sequence of operations do not imply absoluteness unless specifically so stated. Reference to an element in the singular, such as by use of the article “a” or “an”, is not intended to mean “one and only one” unless specifically so stated, but rather “one or more”. As used herein, “and/or” means “and” or “or”, as well as “and” and “or.” As used herein, ranges and subranges mean all ranges including whole and/or fractional values therein and language which defines or modifies ranges and subranges, such as “at least,” “greater than,” “less than,” “no more than,” and the like, mean subranges and/or an upper or lower limit. All structural and functional equivalents to the elements of the various embodiments described throughout the disclosure that are known or later come to be known to those of ordinary skill in the relevant art are intended to be encompassed by the features described and claimed herein. Moreover, nothing disclosed herein is intended to be dedicated to the public regardless of whether such disclosure may ultimately explicitly be recited in the claims. No element or concept disclosed herein or hereafter presented shall be construed under the provisions of 35 USC 112(f) unless the element or concept is expressly recited using the phrase “means for” or “step for”.

In view of the many possible embodiments to which the disclosed principles can be applied, we reserve the right to claim any and all combinations of features and acts described herein, including the right to claim all that comes within the scope and spirit of the foregoing description, as well as the combinations recited, literally and equivalently, in the following claims and any claims presented anytime throughout prosecution of this application or any application claiming benefit of or priority from this application.

What is claimed is:

1. A method of magnetic positioning, positioning a moving target via referring to a plurality of reference magnetic information comprising a plurality of reference magnetic values corresponding to a plurality of axes of reference magnetic field, the method comprising following steps:
detecting a plurality of real-time magnetic information of a moving path along a moving direction of the moving target;
decomposing each of the real-time magnetic information according to a plurality of axes of real-time magnetic field into a plurality of real-time magnetic values and selecting at least one of the real-time magnetic value corresponding to at least one of the axes of real-time magnetic field;
selecting each of the reference magnetic information corresponding to each of the real-time magnetic information and selecting at least one of the axis of reference magnetic field and at least one of the reference magnetic value according to at least one of the axis of real-time magnetic field; and
matching at least one of the real-time magnetic value corresponding to at least one of the axis of real-time magnetic field and at least one of the reference magnetic value corresponding to at least one of the axis of reference magnetic field to position the target.

2. The method of magnetic positioning of claim 1, wherein detecting the plurality of real-time magnetic information of a moving path is implemented via detecting a magnetic information of all magnetic objects in an environment.

3. The method of magnetic positioning of claim 1, wherein the axes of reference magnetic field and/or the axes of real-time magnetic field are built-in axes and/or self-defined axes.

4. The method of magnetic positioning of claim 1, wherein selecting at least one of the axis of real-time magnetic field is implemented according to a calculation of at least one of a magnitude of value, a relative variation and a signal-to-noise ratio of each of the real-time magnetic value corresponding to the axis of real-time magnetic field.

5. The method of magnetic positioning of claim 4, wherein the calculation of at least one of the magnitude of value, the relative variation and the signal-to-noise ratio of each of the real-time magnetic value corresponding to the axis of real-time magnetic field is one-time or continuous.

6. The method of magnetic positioning of claim 1, wherein before matching at least one of the real-time magnetic value corresponding to at least one of the axis of real-time magnetic field and at least one of the reference magnetic value corresponding to at least one of the axis of reference magnetic field, further calibrating at least one of the axis of real-time magnetic field and at least one of the axis of reference magnetic field via linear transformation method.

7. The method of magnetic positioning of claim 1, wherein before and/or after matching at least one of the real-time magnetic value corresponding to at least one of the axis of real-time magnetic field and at least one of the reference magnetic value corresponding to at least one of the axis of reference magnetic field, further filtering at least one of the real-time magnetic value corresponding to at least one of the axis of real-time magnetic field and at least one of the reference magnetic value corresponding to at least one of the axis of reference magnetic field.

8. The method of magnetic positioning of claim 1, wherein matching at least one of the real-time magnetic value corresponding to at least one of the axis of real-time magnetic field and at least one of the reference magnetic value corresponding to at least one of the axis of reference magnetic field is implemented via dynamic programming algorithm, artificial intelligent algorithm, data fusion algorithm, map matching algorithm and any combination thereof.

9. The method of magnetic positioning of claim 1, wherein except for referring to the reference magnetic information, further detecting a plurality of non-magnetic information intermittently or continuously and directly or indirectly matching the real-time magnetic information detected and the non-magnetic information to confirm the corresponding non-magnetic information of the moving target, and the non-magnetic information is selected from pressure information, speed information, acceleration information, angle information, coordinate information, audio information, optical information, image information, radio wave information and any combination thereof.

10. The method of magnetic positioning of claim 9, wherein directly or indirectly matching the real-time magnetic information detected and the non-magnetic information is implemented via dynamic programming algorithm, artificial intelligent algorithm, data fusion algorithm, map matching algorithm and any combination thereof.

11. The method of magnetic positioning of claim 1, wherein except for referring to the reference magnetic information, further referring to a plurality of reference position information intermittently or continuously and directly or indirectly matching the real-time magnetic information detected and the reference position information to confirm the corresponding reference information of the moving target, and the reference position information is selected from magnetic information, location information, coordinate information, terrain information, radio wave information and any combination thereof.

12. The method of magnetic positioning of claim 1, wherein the moving target is selected from land transportations, sea transportations, air transportations and any combination thereof.

13. A system of magnetic positioning, suitable for positioning a moving target moving along a moving path and referring to a database storing a plurality of reference magnetic information comprising at least a reference magnetic value of at least an axis of reference magnetic field correspondingly, the system comprising:
at least a magnetic detecting module, detecting a plurality of real-time magnetic information of the moving path along a moving direction of the moving target; and
at least a calculating module, receiving the real-time magnetic information from the magnetic detecting module and decomposing each of the real-time magnetic information according to a plurality of axes of real-time magnetic field into a plurality of real-time magnetic values, and selecting at least one of the real-time magnetic value corresponding to at least one of the axis of real-time magnetic field to match with the at least one of the reference magnetic values corresponding to at least one of the axes of reference magnetic field for positioning the moving target.

14. The system of magnetic positioning of claim 13, wherein the axes of reference magnetic field and/or the axes of real-time magnetic field are built-in axes and/or self-defined axes.

15. The system of magnetic positioning of claim 13, wherein at least a non-magnetic information are further stored in the database, and the calculating module directly or indirectly calibrates the real-time magnetic information and the non-magnetic information to position the moving target, and the non-magnetic information is selected from pressure information, speed information, acceleration information, angle information, coordinate information, audio information, optical information, image information, radio wave information and any combination thereof.

16. The system of magnetic positioning of claim 13, wherein at least a reference position information are further stored in the database, and the calculating module directly or indirectly calibrates the real-time magnetic information and the reference position information to position the moving target, and the reference position information is selected from magnetic information, location information, coordinate information, terrain information, radio wave information and any combination thereof.

17. The system of magnetic positioning of claim 14, wherein as amounts of the magnetic detecting module are more than one, the magnetic detecting modules are arranged according to the moving path and/or the moving direction.

18. The system of magnetic positioning of claim 13, wherein the magnetic detecting module is installed in the moving target, and the calculating module and the database are selectively installed individually or separately in at least a device or in the moving target.

19. The system of magnetic positioning of claim 13, wherein the moving direction of the moving target is substantially alone a specific path including land routes, water routes and air routes.

20. The method of magnetic positioning of claim 13, wherein the moving target is selected from land transportations, sea transportations, air transportations and any combination thereof.
